(19) United States
(12) Patent Application Publication
(10) Pub. No.: US 2021/0143293 A1
(43) Pub. Date: May 13, 2021

(54) PHOTOELECTRIC DETECTOR

(71) Applicants: Tsinghua University, Beijing (CN); HON HAI PRECISION INDUSTRY CO., LTD., New Taipei (TW)

(72) Inventors: JIN ZHANG, Beijing (CN); YANG WEI, Beijing (CN); SHOU-SHAN FAN, Beijing (CN)

(21) Appl. No.: 16/903,161

(22) Filed: Jun. 16, 2020

(30) Foreign Application Priority Data
Nov. 8, 2019 (CN) 201911089315.7

(51) Int. Cl. H01L 31/109; G01J 1/44; H01L 31/0224; H01L 31/032

(52) U.S. Cl. CPC H01L 31/109; G01J 1/44; G01J 2001/4446; H01L 31/032; H01L 31/022491

(57) ABSTRACT

The present disclosure relates to a photoelectric detector. The photoelectric detector comprises a semiconductor device, a first electrode, a second electrode, and a current detection element. The semiconductor device comprises a semiconductor layer, a first carbon nanotube, and a second carbon nanotube. The semiconductor layer comprises a N-type semiconductor layer and a P-type semiconductor layer, and the semiconductor layer defines a first surface and a second surface. The first carbon nanotube is on the first surface and electrically connected the first electrode. The second carbon nanotube is on the second surface and electrically connected the second electrode. The first carbon nanotube and the second carbon nanotube intersects with each other. A multilayer structure is formed by an overlapping region of the first carbon nanotube, the semiconductor layer, and the second carbon nanotube.

### CROSS-REFERENCE TO RELATED APPLICATIONS

This application claims all benefits accruing under 35 U.S.C. § 119 from Chinese Patent Application No. 201911089315.7, filed on Nov. 8, 2019, in the China Intellectual Property Office, the contents of which are hereby incorporated by reference. This application is also related to copending applications entitled, “LIGHT EMITTING DIODE”, filed **** (Atty. Docket No. US78624). The application is also related to copending applications entitled, “SOLAR BATTERY”, filed **** (Atty. Docket No. US78625). The application is also related to copending applications entitled, “SEMICONDUCTOR STRUCTURE AND SEMICONDUCTOR DEVICE USING THE SAME”, filed **** (Atty. Docket No. US78626).

### FIELD

The present disclosure relates to a photoelectric detector.

### BACKGROUND

Photoelectric detector is a device used to detect light energy. A working principle of the photoelectric detector is based on a photoelectric effect, a conductivity that changes after a material absorbs light radiation energy, so that a presence of light and an amount of light energy can be detected by the photoelectric detector. Semiconductor devices are increasingly used in photoelectric detectors.

However, conventional photoelectric detectors can only work in a single mode; and an application scope of the photoelectric detectors is limited.

### BRIEF DESCRIPTION OF THE DRAWINGS

Implementations of the present technology will now be described, by way of example only, with reference to the attached figures, wherein:

FIG. 1 is a structure schematic view of one embodiment of a photoelectric detector.

FIG. 2 is a side structure schematic view of a semiconductor device of the photoelectric detector of FIG. 1.

FIG. 3 is an aerial view of one embodiment of a photoelectric detector.

FIG. 4 is a side structure schematic view of a semiconductor device of the photoelectric detector of FIG. 2.

FIG. 5 is a scanning photocurrent microscope photo of the photoelectric detector in FIG. 2 at 10V grid voltage.

FIG. 6 is a scanning photocurrent microscope photo of the photoelectric detector in FIG. 2 at 0V grid voltage.

FIG. 7 is a scanning photocurrent microscope photo of the photoelectric detector in FIG. 2 at −10V grid voltage.

FIG. 8 is a photo response diagram of the photoelectric detector of FIG. 2.

### DETAILED DESCRIPTION

The disclosure is illustrated by way of example and not by way of limitation in the figures of the accompanying drawings in which like references indicate similar elements. It should be noted that references to “another,” “an,” or “one” embodiment in this disclosure are not necessarily to the same embodiment, and such references mean “at least one.”

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts have been exaggerated to illustrate details and features of the present disclosure better.

Several definitions that apply throughout this disclosure will now be presented.

The term “substantially” is defined to be essentially conforming to the particular dimension, shape, or other feature which is described, such that the component need not be exactly or strictly conforming to such a feature. The term “comprise,” when utilized, means “include, but not necessarily limited to”; it specifically indicates open-ended inclusion or membership in the so-described combination, group, series, and the like.

Referring to FIG. 1 and FIG. 2, one embodiment is described in relation to a photoelectric detector 10. The photoelectric detector 10 comprises a semiconductor device 100, a first electrode 202, a second electrode 204, and a current detection element 212. A circuit is formed by the semiconductor device 100, the first electrode 202, the second electrode 204, and the current detection element 212.

The semiconductor device 100 comprises a first carbon nanotube 102, a semiconductor layer 104, and a second carbon nanotube 106. The semiconductor layer 104 is sandwiched between the first carbon nanotube 102 and the second carbon nanotube 106. The semiconductor layer 104 defines a first surface 1046 and a second surface 1048 opposite to the first surface 1046. The first carbon nanotube 102 is located on the first surface and is in direct contact with the first surface. The second carbon nanotube 106 is located on the second surface 1048 and is in direct contact with the second surface 1048. The semiconductor layer 104 comprises an N-type semiconductor layer 1042 and a P-type semiconductor layer 1044, and the N-type semiconductor layer 1042 and the P-type semiconductor layer 1044 are stacked with each other. Each of the N-type semiconductor layer 1042 and the P-type semiconductor layer 1044 is a two-dimensional material. The two-dimensional material refers to a material in which electrons can perform plane movement freely only on a nanometer scale (1-100 nm) in two dimensions, such as nanofilms, superlattices, quantum wells, etc. A first extending direction of the first carbon nanotube intersects with a second extending direction of the second carbon nanotube.

In one embodiment, only a single first carbon nanotube 102 is on the first surface 1046 of the semiconductor layer 104, that is, the number of the first carbon nanotube 102 is only one. The first carbon nanotube 102 is a metal carbon nanotube. The first carbon nanotube 102 can be a single-walled carbon nanotube, a double-walled carbon nanotube, or a multi-walled carbon nanotube. In one embodiment, a diameter of the first carbon nanotube 102 ranges from 0.5 nanometers to 100 nanometers. In one embodiment, the diameter of the first carbon nanotube 102 ranges from 0.5 nanometers to 10 nanometers. In one embodiment, the first carbon nanotube 102 is the single-walled carbon nanotube, and the diameter of the first carbon nanotube 102 ranges from 0.5 nanometers to 2 nanometers. In one embodiment, the diameter of the first carbon nanotube 102 is 1.0 nanometer.

In one embodiment, the first carbon nanotube 102 is an inner shell carbon nanotube. The inner shell carbon nanotube refers to the innermost carbon nanotube of the double-walled carbon nanotube or the multi-walled carbon nanotube. The inner shell carbon nanotubes can be pulled from an ultra-long double-walled carbon nanotube or an ultra-long multi-walled carbon nanotube. A length of the ultra-long double-walled carbon nanotube or the ultra-long multi-walled carbon nanotube is larger than 150 micrometers. In one embodiment, the length of the ultra-long double-walled carbon nanotube or the ultra-long multi-walled carbon nanotube ranges from 150 micrometers to 300 micrometers. A method of obtaining the inner shell carbon nanotube comprises stretching two ends of the ultra-long double-walled carbon nanotube or the ultra-long multi-walled carbon nanotube, where outer walls of the ultra-long double-walled carbon nanotubes or the ultra-long multi-walled carbon nanotubes are sheared off in the middle part under tension, and the innermost wall of carbon nanotube remains in the middle part of the ultra-long double-walled carbon nanotube or the ultra-long multi-walled carbon nanotube, and selecting a section of the innermost wall of carbon nanotube to obtain the inner shell carbon nanotube. The inner shell carbon nanotube provides a clean surface with no impurities on a surface of the inner shell carbon nanotube, therefore, the first carbon nanotube 102 can be in good contact with the semiconductor layer 104. The first carbon nanotube 102 is not limited to the inner shell carbon nanotube, the first carbon nanotube 102 can also be other single-walled carbon nanotubes, double-walled carbon nanotubes, or multi-walled carbon nanotubes.

The N-type semiconductor layer 1042 and the P-type semiconductor layer 1044 are stacked with each other. A p-n junction is formed by the N-type semiconductor layer 1042 and the P-type semiconductor layer 1044 in a direction perpendicular to the semiconductor layer 104. The semiconductor layer 104 is a two-dimensional layered structure having a thickness of nanometer size, and the thickness is measured in a direction being perpendicular to the first surface. When the thickness of the semiconductor layer 104 is too large, such as, larger than 200 nanometers, a current modulation effect of the semiconductor structure 100 is limited. In one embodiment, the thickness of the semiconductor layer 104 ranges from 1.0 nanometer to 200 nanometers. In one embodiment, a thickness of the N-type semiconductor layer 1042 ranges from 0.5 nanometers to 100 nanometers. In one embodiment, a thickness of the N-type semiconductor layer 1042 ranges from 0.5 nanometers to 50 nanometers. In one embodiment, a thickness of the P-type semiconductor layer 1044 ranges from 0.5 nanometers to 100 nanometers. In one embodiment, a thickness of the P-type semiconductor layer 1044 ranges from 0.5 nanometers to 50 nanometers. In one embodiment, the N-type semiconductor layer 1042 is in direct contact with the first carbon nanotube 102, and the P-type semiconductor layer 1044 is in direct contact with the second carbon nanotube 106. In some other embodiments, the N-type semiconductor layer 1042 is in direct contact with the second carbon nanotube 106, and the P-type semiconductor layer 1044 is in direct contact with the first carbon nanotube 102.

A material of the P-type semiconductor layer 1044 and a material of the N-type semiconductor layer 1042 can be an inorganic compound semiconductor, an element semiconductor, an organic semiconductor material, or a material doped with the inorganic compound semiconductor, the element semiconductor, or the organic semiconductor material. In one embodiment, the material of the N-type semiconductor layer 1042 is molybdenum disulfide (MoS₂), and the thickness of the N-type semiconductor layer 1042 is 16 nanometers; and the material the P-type semiconductor layer 1044 is tungsten diselenide (WSe₂), and the thickness of the P-type semiconductor layer 1044 is 14 nanometers. In one embodiment, the material of the N-type semiconductor layer 1042 is MoS₂, and the thickness of the N-type semiconductor layer 1042 is 7.6 nanometers; and the material the P-type semiconductor layer 1044 is WSe₂, and the thickness of the P-type semiconductor layer 1044 is 76 nanometers.

In one embodiment, only a single second carbon nanotube 106 is on the second surface 1048 of the semiconductor layer 104, that is, the number of the second carbon nanotube 106 is only one. The second carbon nanotube 106 is a metal carbon nanotube. The second carbon nanotube can be a single-walled carbon nanotube, a double-walled carbon nanotube, or a multi-walled carbon nanotube. In one embodiment, a diameter of the second carbon nanotube 106 ranges from 0.5 nanometers to 100 nanometers. In one embodiment, the diameter of the second carbon nanotube 106 ranges from 0.5 nanometers to 10 nanometers. In another embodiment, the second carbon nanotube 106 is a single-walled carbon nanotube, and the diameter of the second carbon nanotube 106 ranges from 0.5 nanometers to 2.0 nanometers. In one embodiment, the diameter of the second carbon nanotube 106 is 1.0 nanometer. In one embodiment, the second carbon nanotube 106 is the same as the first carbon nanotube 102, and the second carbon nanotube 106 is the inner shell carbon nanotube. The inner shell carbon nanotube provides a clean surface with no impurities on a surface of the inner shell carbon nanotube, therefore, the second carbon nanotube 106 can be in good contact with the semiconductor layer 104. The second carbon nanotube 106 is not limited to the inner shell carbon nanotube, and the second carbon nanotube 106 can also be other single-walled carbon nanotubes, double-walled carbon nanotubes, or multi-walled carbon nanotubes.

The first extending direction of the first carbon nanotube 102 intersects with the second extending direction of the second carbon nanotube 106 refers to that an angle is formed between the first extending direction and the second extending direction. The angle is larger than 0 degree and less than or equal to 90 degrees. In one embodiment, the first extending direction is perpendicular to the second extending direction, that is, the angle is 90 degrees.

Referring to FIG. 2, at an intersection of the first carbon nanotube 102 and the second carbon nanotube 106, and in a direction perpendicular to the semiconductor layer 104, a multilayer structure 108 is formed by in an overlapping region of the first carbon nanotube 102, the semiconductor layer 104, and the second carbon nanotube 106. The multilayer structure 108 defines a lateral cross section and a longitudinal section. The lateral cross section is a cross section parallel to a major surface of the semiconductor layer 104. The longitudinal section is a section perpendicular to the major surface of the semiconductor layer 104. Since a size of the first carbon nanotube 102 and a size of the second carbon nanotube 106 are smaller relative to the semiconductor layer 104, an area of the lateral cross section is determined by the diameter of the first carbon nanotube 102 or the second carbon nanotube 106, the area of the lateral cross section of the multilayer structure 108 is also in nanometer size. An area of the longitudinal section is determined by the diameter of the first carbon nanotube 102, the diameter of the second carbon nanotube 106 and the thickness of the semiconductor layer 104. The diameter of the first carbon nanotube 102 and the diameter of the second carbon nanotube 106 are both in nanometers, and the thickness of the semiconductor layer 104 is also in nanometers; therefore, the area of the longitudinal section of the multilayer structure 108 is also in nanometers. In one embodiment, the area of the lateral cross section of the multilayer structure 108 ranges from 1.0 square nanometer to 100 square nanometers. Therefore, a vertical point p-n junction can be formed by at the intersection of the first carbon nanotube 102 and the second carbon nanotube 106 in the overlapping region. The vertical point p-n junction is van der Waals heterojunction.

In use of the photoelectric detector 10, the first carbon nanotube 102 and the second carbon nanotube 106 are used as two electrodes located on two opposite surfaces of the semiconductor layer 104. When light is irradiated on the surface of the semiconductor layer 104, a current is generated in the circuit formed by the semiconductor device 100, the first electrode 202, the second electrode 204, and the current detection element 212, and a current flow path is the lateral cross section through the multilayer structure 108; therefore, an effective portion of the semiconductor device 100 is the multilayer structure 108. A size of the semiconductor device 100 only needs to be larger than a volume of the multilayer structure 108. Therefore, sizes of the semiconductor device 100 can be reduced to nano-sizes, and the photoelectric detector 10 using the semiconductor device 100 can also have a small size. The photoelectric detector 10 has low power consumption, nanometer-sized size, and high integration.

The first electrode 202 and the second electrode 204 are made of conductive material, such as metal, Indium Tin Oxides (ITO), Antimony Tin Oxide (ATO), conductive silver paste, carbon nanotubes or any other suitable conductive materials. The metal can be aluminum, copper, tungsten, molybdenum, gold, titanium, palladium or any combination of alloys. In one embodiment, the first electrode 202 and the second electrode 204 are both conductive films. A thickness of the conductive film is ranged from 2.0 nanometers to 100 microns. In one embodiment, the first electrode 202 and the second electrode 204 are metal composite structures formed by compounding metal Au on a surface of metal Ti. A thickness of the metal Ti is about 5.0 nanometers. A thickness of the metal Au is about 60 nanometers. In one embodiment, the first electrode 202 is located at one end of the first carbon nanotube 102 and adhered to a surface of the first carbon nanotube 102, and the second electrode 204 is located at one end of the second carbon nanotube 106 and adhered to a surface of the second carbon nanotube 106.

The photoelectric detector 10 can be used as a qualitative detection of light. The working principle of the photoelectric detector 10 comprises: if no light is irradiated on the photoelectric detector 10, the semiconductor device 100 is on off-status, and no current passes through the circuit formed by the semiconductor device 100, the first electrode 202, the second electrode 204, the current detection element 212 cannot detect a current; if a light is emitted on the photoelectric detector 10, photogenerated carriers are produced in the semiconductor layer 104, a built-in electric field formed between the first carbon nanotube 102 and the second carbon nanotube 106 separates photo-generated electron-hole pairs, a photo-generated current is formed, that is, a current is generated in the circuit formed by the semiconductor device 100, and the current is detected in the current detection element 212.

The photoelectric detector 10 can also be used as a quantitative detection of light. The working principle of the photoelectric detector 10 comprises: turning on power, applying a voltage between the first electrode 202 and the second electrode 204, emitting light with different strength on the semiconductor layer 104 in turn, reading the different current values corresponding to light with different strength, and drawing a graph about light strength and current values. When a light with unknown strength is emitted on the semiconductor layer 104, a current value corresponding the light can be detected, and according to the graph about light strength and current values, the strength of the light can be known.

The semiconductor device 100 is formed by one first carbon nanotube and one second carbon nanotube, sandwiching a two-dimensional semiconductor layer containing a vertical p-n junction, and the first carbon nanotube and the second carbon nanotube are used as electrodes. Since electric field shielding of carbon nanotubes is weak, and the doping of nanomaterials in carbon nanotubes and heterojunctions can be easily regulated by the electric field, a doped state of nanomaterials in carbon nanotubes and p-n junctions is changed under electric field modulation; therefore, the heterojunction formed in the semiconductor layer 104 of the photoelectric detector 10 can be switched between a p-p junction, p-n junction and an n-n junction under electric field modulation, and the photoelectric detector 10 can work in three different modes. In used, there is no need to replace the photoelectric detector; light in multiple modes can be detected to achieve different performance by adjusting the electric field, which is impossible with conventional photoelectric detectors. For example, conventional photoelectric detectors can not simultaneously achieve high-resolution and high-response detection; different photoelectric detectors are needed for high-resolution detection and high responsiveness detection. The photoelectric detector 10 can switch different working modes only by adjusting the electric field to simultaneously achieve high-resolution and high-response detection, and does not need to replace the photoelectric detector.

Referring to FIG. 3 and FIG4, one embodiment is described in relation to a photoelectric detector 20. The photoelectric detector 20 is the same as the photoelectric detector 10 except that the photoelectric detector 20 further comprises a third electrode 206 and an insulating layer 208. The semiconductor device 100 is electrically connected to the first electrode 202 and the second electrode 204, and the third electrode 206 is insulated from the semiconductor device 100, the first electrode 202 and the second electrode 204 through the insulating layer 208.

The third electrode 206 is a layered structure. The insulating layer 208 is located on and in direct contact with the third electrode 206. The first electrode 202, the second electrode 204, and the semiconductor device 100 are located on the insulating layer 208. The first electrode 202, the second electrode 204, and the semiconductor device 100 are supported by the third electrode 206 and the insulating layer 208. In one embodiment, the second carbon nanotube 106 is directly located on a surface of the insulating layer 208 away from the third electrode 206. The second carbon nanotube 106 is close to the third electrode 206, and the first carbon nanotube 102 is far from the third electrode 206; a shielding effect between the semiconductor layer 104 and the third electrode 206 is not generated by the first carbon nanotube 102. Therefore, in used, the semiconductor device 100 can be controlled by the third electrode 206, and the photoelectric performance of the photoelectric detector 20 is controllable.

A material of the insulating layer 208 is an insulating material. The material of the insulating layer 208 can be hard materials such as silicon nitride or silicon oxide. The material of the insulating layer 208 can also be flexible materials such as benzocyclobutene (BCB), polyester or acrylic resin. A thickness of the insulating layer 208 can be ranged from 2 nanometers to 100 micrometers. In one embodiment, the material of the insulating layer 208 is silicon nitride, and the thickness of the insulating layer 208 is 50 nanometers.

The third electrode 206 is made of conductive material, such as metal, Indium Tin Oxides (ITO), Antimony Tin Oxide (ATO), conductive silver paste, carbon nanotubes or any other suitable conductive materials. The metal can be aluminum, copper, tungsten, molybdenum, gold, titanium, palladium or any combination of alloys. The third electrode 206 is used as a control electrode of the semiconductor device 100. The third electrode 206 can be regarded as a gate electrode of the photoelectric detector 20.

In one embodiment, the photoelectric detector 20 further comprises a substrate 210. The third electrode 206, the insulating layer 208, and the semiconductor device 100 are sequentially stacked in a said order on a surface of the substrate 210 and supported by the substrate 210. A material of the substrate 210 is non-light-absorbing material. In one embodiment, the material of the substrate 210 is silicon. The substrate 210 is a selectable element.

FIGS is a microscope photo corresponding to a scanning photocurrent of the photoelectric detector 20 when a light intensity is 0.236 μW a source-drain voltage is 0V, and a grid voltage is 10V. It can be seen that when the grid voltage is 10V, the scanning photocurrent of the photoelectric detector 20 shows a vertical line mode. FIG. 6 is a microscope photo corresponding to a scanning photocurrent of the photoelectric detector 20 when a light intensity is 0.236 μW, a source-drain voltage is 0V, and a grid voltage is 0V. It can be seen that when the grid voltage is 10V, the scanning photocurrent of the photoelectric detector 20 shows a horizontal line mode. FIG. 7 is a microscope photo corresponding to a scanning photocurrent of the photoelectric detector 20 when a light intensity is 0.236 μW, a source-drain voltage is 0V, and a grid voltage is −10V. It can be seen that when the grid voltage is −10V, the scanning photocurrent of the photoelectric detector 20 shows a point mode. FIGS. 5-7 illustrate that the photoelectric detector 20 can be switched between three working modes by regulating the grid voltage.

FIG. 8 is optical response performance diagrams of two photoelectric detectors with different thicknesses of MoS₂ layer and WSe₂ layer. Where one photoelectric detector has 7.6 nanometers MoS₂ layer and the 76 nanometers WSe₂ layer, and another photoelectric detector has 16 nanometers MoS₂ layer and 14 nanometers WSe₂ layer. It can be seen that the light responsivity of each of the two photoelectric detectors is large. Especially, when the grid voltage is −10V, the thickness of the MoS₂ layer is 7.6 nanometers, and the thickness of the WSe₂ layer is 76 nanometers, the light responsivity of the photoelectric detector can reach 216 mA/W, which is much higher than conventional photoelectric detectors. When the grid voltage is −10V, an external quantum efficiency of the photoelectric detector can reach 41.7%. Therefore, the photoelectric detector has great potential.

The photoelectric detector of the present disclosure has following characters. First, the semiconductor device is formed by two intersecting carbon nanotubes sandwiching a two-dimensional semiconductor layer containing vertical p-n junction. The first carbon nanotube and the second carbon nanotube are used as electrodes. Since electric field shielding of carbon nanotubes is weak, and the doping of nanomaterials in carbon nanotubes and heterojunctions can be easily regulated by the electric field, a doped state of nanomaterials in carbon nanotubes and p-n junctions is changed under electric field modulation; therefore, the heterojunction formed in the semiconductor layer of the photoelectric detector can be switched between a p-p junction, a p-n junction and an n-n junction under electric field modulation, and the photoelectric detector can work in three different modes. Second, the semiconductor device is formed by two intersecting carbon nanotubes sandwiching a two-dimensional semiconductor layer. Since the diameters of the two carbon nanotubes are in nanometer size, at the intersection of the two carbon nanotubes, a nano-sized vertical point p-n junction is formed at the overlapping region of the two carbon nanotubes and the semiconductor layer. The size of the semiconductor device only needs to be larger than the volume of the overlapping area. Therefore, the size of the semiconductor device can be reduced to a nano-size, and a nano-size photoelectric detector is obtained. Nano-sized photoelectric detectors will have important applications in the fields of future nanoelectronics and nano-optoelectronics. Third, each of the two electrodes of the light emitting diode is a carbon nanotube. Since absorption or reflection of light by carbon nanotubes can be neglectable and carbon nanotubes have excellent light transmission, the photoelectric detector of the present disclosure has high photoelectric detection efficiency. Fourth, the built-in potential of the semiconductor device is large, so the photoelectric detector of the present invention is excellent in terms of photodetector power consumption and zero bias signal-to-noise ratios. Fifth, the vertical point p-n heterojunction in the semiconductor device of the photoelectric detector is formed by vertically stacking different types of semiconductor layers, compared with the lateral p-n heterojunction, the photoelectric detector of the present invention has shorter diffusion distance, lower leakage current, and higher light-induced carrier extraction efficiency.

It is to be understood that the above-described embodiments are intended to illustrate rather than limit the present disclosure. Variations may be made to the embodiments without departing from the spirit of the present disclosure as claimed. Elements associated with any of the above embodiments are envisioned to be associated with any other embodiments. The above-described embodiments illustrate the scope of the present disclosure but do not restrict the scope of the present disclosure.

Depending on the embodiment, certain of the steps of a method described may be removed, others may be added, and the sequence of steps may be altered. The description and the claims drawn to a method may include some indication in reference to certain steps. However, the indication used is only to be viewed for identification purposes and not as a suggestion as to an order for the steps.

What is claimed is:

1. A photoelectric detector comprising:
a semiconductor device, a first electrode, a second electrode, and a current detection element, wherein a circuit is formed by the semiconductor device, the first electrode, the second electrode, and the current detection element; and the semiconductor device comprises:
a semiconductor layer comprising an N-type semiconductor layer and a P-type semiconductor layer stacked with each other, and the semiconductor layer defining a first surface and a second surface opposite to the first surface;
a first carbon nanotube on the first surface and in direct contact with the first surface, wherein the first carbon nanotube extends in a first extending direction and is electrically connected the first electrode; and
a second carbon nanotube on the second surface and in direct contact with the second surface, wherein the second carbon nanotube extends in a second extending direction intersecting with the first extending direction and is electrically connected the second electrode; and
a multilayer structure formed by an overlapping region of the first carbon nanotube, the semiconductor layer, and the second carbon nanotube.

2. The photoelectric detector of claim 1, wherein only a single first carbon nanotube is located on the first surface of the semiconductor layer.

3. The photoelectric detector of claim 1, wherein only a single second carbon nanotube is located on the second surface of the semiconductor layer.

4. The photoelectric detector of claim 1, wherein each of the first carbon nanotube and the second carbon nanotube is an inner shell carbon nanotube, and the inner shell carbon nanotube is an innermost wall of a double-walled carbon nanotube or a multi-walled carbon nanotube.

5. The photoelectric detector of claim 4, wherein the inner shell carbon nanotube is pulled from an ultra-long double-walled carbon nanotube or an ultra-long multi-walled carbon nanotube, and a length of the ultra-long double-walled carbon nanotube or the ultra-long multi-walled carbon nanotube is larger than 150 micrometers.

6. The photoelectric detector of claim 5, wherein the length of the ultra-long double-walled carbon nanotube or the ultra-long multi-walled carbon nanotube ranges from approximately 150 micrometers to approximately 300 micrometers.

7. The photoelectric detector of claim 1, wherein a diameter of the first carbon nanotube ranges from 0.5 nanometers to 10 nanometers.

8. The photoelectric detector of claim 1, wherein a diameter of the second carbon nanotube ranges from 0.5 nanometers to 10 nanometers.

9. The photoelectric detector of claim 1, wherein the semiconductor layer is a two-dimensional layered structure with a thickness ranges from 1.0 nanometer to 200 nanometers, and the thickness is measured in a direction being perpendicular to the first surface.

10. The photoelectric detector of claim 1, wherein a thickness of the N-type semiconductor layer ranges from 0.5 nanometers to 50 nanometers, and a thickness of the P-type semiconductor layer ranges from approximately 0.5 nanometers to approximately 50 nanometers.

11. The photoelectric detector of claim 1, wherein a material of the N-type semiconductor layer is molybdenum disulfide, and a material of the P-type semiconductor layer is tungsten diselenide.

12. The photoelectric detector of claim 1, wherein the first extending direction is perpendicular to the second extending direction.

13. The photoelectric detector of claim 1, the multiplayer structure comprising a vertical point p-n junction at a region where the first carbon nanotube and the second carbon nanotube overlaps.

14. The photoelectric detector of claim 13, wherein the vertical point p-n junction is a Van der Waals van der Waals heterojunction.

15. The photoelectric detector of claim 1, wherein each of the first electrode and the second electrode is a metal composite structure comprising metal titanium (Ti); and metal gold (Au) compounded on surfaces of the metal Ti.

16. The photoelectric detector of claim 15, wherein a thickness of the metal Ti is 5.0 nanometers, and a thickness of the metal Au is 60 nanometers.

17. The photoelectric detector of claim 1, wherein an area of a lateral cross section of the multilayer structure ranges from 1.0 square nanometer to 100 square nanometers, and the lateral cross section is parallel to the first extending direction and the second extending direction.

18. The photoelectric detector of claim 1, further comprising a third electrode and an insulating layer, wherein the semiconductor device is electrically connected to the first electrode and the second electrode, and the third electrode is insulated from the semiconductor device, the first electrode and the second electrode through the insulating layer.

19. The photoelectric detector of claim 18, wherein the third electrode is a layered structure, the insulating layer is on and in direct contact with the third electrode; and the first electrode, the second electrode, and the semiconductor device are on the insulating layer.

20. The photoelectric detector of claim 18, further comprising a substrate; and the third electrode, the insulating layer, and the semiconductor device are sequentially stacked in said order on a surface of the substrate and supported by the substrate.
